(19) United States
(12) Patent Application Publication
(10) Pub. No.: US 2025/0208222 A1
(43) Pub. Date: Jun. 26, 2025

(54) QUALITY INSPECTION DEVICE AND METHOD OF POUCH TYPE SECONDARY BATTERY CELLS

(71) Applicants: OSUNG HITECH CO., LTD, Daegu (KR); JEONGAN SYSTEM CO., LTD, Daegu (KR)

(72) Inventors: Sae Don OH, Daegu (KR); Jeong Hak PARK, Daegu (KR)

(21) Appl. No.: 19/079,508

(22) Filed: Mar. 14, 2025

Related U.S. Application Data
(63) Continuation of application No. PCT/KR2022/015093, filed on Oct. 7, 2022.

(51) Int. Cl. G01R 31/385; G01R 31/389; G01R 31/392; H01M 10/42

(52) U.S. Cl. CPC G01R 31/3865; G01R 31/389; G01R 31/392; H01M 10/4285

(57) ABSTRACT

Provided is a quality inspection device and method for a pouch-type secondary battery cell, which inspects the quality of a plate, a bent portion, or a weld portion of a pouch-type secondary battery cell. An AC signal generating unit generates an AC signal. A magnetic field generating unit generates a magnetic field in accordance with the generated AC signal and induces a current to flow in a pouch-type secondary battery cell. At least one induced current detection sensors each detect the signal of the induced current flowing in the pouch-type secondary battery cell. A control/judgment unit compares the detected induced current signal with a value of a preset judgment range and judges the quality of the pouch-type secondary battery cell.

### TECHNICAL FIELD

The present invention relates to a quality inspection device and method for a pouch-type secondary battery cell, which inspects the quality of a plate, a bent portion, or a weld portion in a pouch-type secondary battery cell.

### BACKGROUND OF THE INVENTION

Fossil fuels, widely used as energy sources, are gradually depleting, and their prices continue to rise. Additionally, the combustion of fossil fuels produces pollutants, such as soot, which harm the environment. In particular, vehicles powered by fossil fuels release significant pollutants, contributing to severe environmental damage. This calls for urgent measures to reduce fossil fuel consumption, especially in vehicles.

As a result, there is a growing demand for alternative energy sources that are environmentally friendly and can be used across various industries without polluting the environment.

There are several known environmentally friendly alternative energy sources that do not emit pollutants. As one of these environmentally friendly alternative energy sources, secondary batteries are emerging as a key solution. These batteries can store and repeatedly release electricity, serving as an eco-friendly power source for power devices.

Secondary batteries are gaining attention due to their environmental benefits and energy efficiency. They offer a significant reduction in fossil fuel usage and do not generate harmful by-products.

Recently, they are widely used in many industries, including in portable devices like smartphones, electric vehicles (EVs), hybrid vehicles (HVs), and other high-power applications. The energy capacity of secondary batteries is also continuously increasing.

Among the types of secondary batteries, pouch-type secondary batteries are widely used. These batteries are made by combining several pouch-type cells.

The pouch-type secondary battery cell is built by layering an anode and cathode plate with a separator in between. Then, the electrodes of the laminated anode and cathode plates are respectively compressed, and an anode terminal and a cathode terminal are respectively welded to the electrodes of the compressed anode and cathode plates. In addition, the laminated anode plates, separator, and cathode plates are configured to be wrapped by a pouch made of, for example, an aluminum film together with an electrolyte.

The pouch-type secondary battery cells are designed so that only the anode and cathode terminals are exposed.

Pouch-type secondary battery cells can be manufactured with minimal internal deformation or empty space. Additionally, because the pouch-type secondary battery cells can be manufactured in various shapes, these cells offer advantages such as lightweight, high energy density, and a high degree of design flexibility.

However, various defects may arise during the manufacturing process of these pouch-type secondary battery cells.

For example, in the process of laminating the anode and cathode plates by interposing a separator between them, defects such as microscopic cracks or short circuits may occur in the anode and cathode plates.

In addition, in the process of pressing the electrodes of the plurality of anode and cathode plates, a bent portion is generated between the ends of the anode and cathode plates and the electrodes. When the bent portion is bent, defects such as microscopic cracks or short circuits may occur.

In addition, during the process of welding the anode terminal and cathode terminal to the pressed electrodes, a weld defect may occur in which the electrodes are not welded to the anode terminal and cathode terminal.

These defects impede the flow of current that charges and discharges the pouch-type secondary battery cell. As a result, the current flowing to the defective area decreases, and the current flow is relatively concentrated in the area where the defect does not occur.

Therefore, a large amount of current may flow in the area where no defects have occurred, which may cause overheating. In addition, overheating may occur in the area where a defect has occurred due to the high resistance value. This overheating may cause a safety accident such as a fire in the secondary battery.

Accordingly, after manufacturing a pouch-type secondary battery cell, a highly reliable inspection device is required that can precisely inspect whether defects such as cracks or short circuits have occurred in the entire portion of the pouch-type secondary battery cell, i.e., the anode and cathode electrode plates, or the bent portions of the electrodes, and whether there are weld defects in the electrodes.

One existing solution for inspecting the quality of pouch-type cells is disclosed in Korean Patent No. 10-2023739, registered on Sep. 16, 2019.

According to the above-mentioned prior art, the present invention comprises: a first sensor for inducing an eddy current into a secondary battery cell; and a second sensor for detecting an eddy current signal induced by the first sensor; an inspection unit for performing an inspection using eddy current while the secondary battery cell is in motion; a transport unit for sequentially transporting a plurality of secondary battery cells from a point where the secondary battery cells are inserted to a point where they are taken out; and a control unit electrically connected to the inspection unit for receiving, evaluating, and controlling an eddy current signal detected by the inspection unit. The inspection unit is designed to be able to move the first sensor and the second sensor to a position to be inspected, and is configured to perform an inspection using eddy current while the first sensor and the second sensor are fixed, thereby detecting a crack inside a pouch-type secondary battery cell using eddy current.

This prior art can detect the presence and location of microscopic cracks or short circuits in the anode and cathode electrode plates and electrode areas of a pouch-type secondary battery cell using eddy currents in a non-destructive manner, and can also detect the presence or absence of weld defects in welded joints.

In general, when manufacturing pouch-type secondary battery cells, the height, angle, and width of the bent portion are not constant and occur in various forms. In addition, the location, direction, width, and shape of the portion where cracks or short circuits occur are not constant and occur in various forms. In addition, due to the influence of electrolyte and welds, the manufactured pouch-type secondary battery cells are not uniform and there are slight differences between them.

The above-mentioned eddy current method is very sensitive to the measurement distance between the pouch-type secondary battery cell and the sensors. That is, depending on the measurement distance, the characteristics of defects in the electrode plates and bent portion of the pouch-type secondary battery cell and weld defects in the weld portion of the electrodes are detected differently.

Therefore, the above-mentioned prior art has limitations in precisely inspecting whether a pouch-type secondary battery cell is defective or not.

In addition, the prior art is to inspect whether the pouch-type secondary battery cells is defective or not by incurring a eddy current only in a local area, and thus has limitations in precisely detecting defects across the entire surface of the pouch-type secondary battery cells, including the electrodes and weld portions.

Furthermore, it is difficult to detect whether the pouch-type secondary battery cells is defective or not if there are deformations in the cells or positional errors between the pouch-type secondary battery cells and the sensors.

Therefore, the above-mentioned prior art is hardly put to practical use.

### PRIOR ART LITERATURE

### Patent Document

(Patent Document 1) Republic of Korea Patent No. 10-2023739 (registered on Sep. 16, 2019)

### DETAILS OF THE INVENTION

### Problem to be Solved by the Invention

The problem to be solved by the present invention is to provide a quality inspection device and method for a pouch-type secondary battery cell, which can precisely inspect whether microscopic cracks or short circuits have occurred in the plates or bent portions of the pouch-type secondary battery cell. This is achieved by inducing a current to flow throughout the entire pouch-type secondary battery cell and detecting the induced current in the plates or bent portions of the pouch-type secondary battery cell.

In addition, the problem to be solved by the present invention is to provide a quality inspection device and method for a pouch-type secondary battery cell, which can precisely inspect whether there is a weld defect in a welded portion. By inducing a current to flow throughout the entire pouch-type secondary battery cell and detecting the induced current at a weld portion of an electrode, the invention ensures accurate inspection of potential weld defects.

In addition, the problem to be solved by the present invention is to provide a quality inspection device and method for a pouch-type secondary battery cell, which can accurately detect the location of a defect, such as a microscopic crack or short circuit, when a defect occurs in a plate or a bent portion of a pouch-type secondary battery cell.

In addition, the problem to be solved by the present invention is to provide a quality inspection device and method for a pouch-type secondary battery cell, which can accurately detect the location where a weld defect has occurred in a weld portion of a pouch-type secondary battery cell.

In addition, the problem to be solved by the present invention is to provide a quality inspection device and method for a pouch-type secondary battery cell, which can inspect the quality of a pouch-type secondary battery cell with minimal influence from external factors such as dust or moisture or noise signals.

In addition, the problems to be solved by the present invention are not limited to the problems mentioned above, and other problems not mentioned can be clearly understood by a person having ordinary skill in the technical field to which the present invention belongs from the description below.

### Means of Solving the Problem

According to the quality inspection device of a pouch-type secondary battery cell of the present invention, it may comprise an AC signal generating unit that generates an AC signal, a magnetic field generating means that generates a magnetic field according to the AC signal and induces a current to flow in the pouch-type secondary battery cell, at least one induced current detection sensors for detecting a signal of the induced current flowing in the pouch-type secondary battery cell, and a control/judgment unit for comparing the signal value of the induced current detected by the induced current detection sensor with a value of a preset judgment range and determines the quality of the pouch-type secondary battery cell based on the comparison result.

In addition, the quality inspection device for a pouch-type secondary battery cell of the present invention further comprises a power loss detection unit for detecting power loss of an AC signal generated by the AC signal generation unit. The control/judgment unit can determine, based on a detection signal of the power loss detection unit, whether the at least one induced current detection sensor is positioned at a start position where it starts detecting an induced current from the pouch-type secondary battery cell.

The magnetic field generating means may comprise a transformer that transmits the AC current generated by the AC signal generating unit, a series resonance unit that resonates in series with a low frequency of the AC current to cause the coil to generate a magnetic field, and a parallel resonance unit that resonates in parallel with a high frequency of the AC current to cause the coil to generate a magnetic field.

In addition, the quality inspection device for a pouch-type secondary battery cell of the present invention may further comprise at least one signal processing unit for outputting a signal of an induced current detected by the induced current detection sensor to the control/judgment unit. The AC signal generation unit may generate an AC signal with dual frequencies, comprising both low frequency and high frequency. The signal processing unit may comprise a low-frequency detection filter for detecting the low-frequency AC current signal and outputting it to the control/judgment unit, and a high-frequency detection filter for detecting the high-frequency AC current signal and outputting it to the control/judgment unit.

In addition, in the quality inspection device for a pouch-type secondary battery cell of the present invention, the at least one induced current detection sensors move and scan the pouch-type secondary battery cell to detect an induced current signal when the pouch-type secondary battery cell is positioned at the starting position.

In addition, in the quality inspection device for a pouch-type secondary battery cell of the present invention, he pouch-type secondary battery cell and the at least one inductive current detection sensor are fixed, and the pouch-type secondary battery cell moves such that the induced current signal is detected by being scanned by the at least one inductive current detection sensor.

Between the magnetic field generating means and the induced current detection sensor, a shielding means for shielding the magnetic field of the magnetic field generating means may be further comprised.

And the quality inspection method of the pouch-type secondary battery cell of the present invention may comprises a step in which an AC signal generating unit generates an AC signal, and a magnetic field generating means generates a magnetic field according to the generated AC signal and induces a current to flow in the pouch-type secondary battery cell; a step in which an inductive current detection sensor detects a signal of an induced current flowing into the pouch-type secondary battery cell; and a step of in which a control/judgment unit compares the signal of the induced current detected by the inductive current detection sensor with a value within a judgment criterion range to determine the quality of the pouch-type secondary battery cell.

### Effect of the Invention

According to the quality inspection device and method of the pouch-type secondary battery cell of the present invention, an induced current is caused to flow through the pouch-type secondary battery cell. Then, the induced current flowing through the pouch-type secondary battery cell is detected at the electrode plate and the bent portion to determine whether cracks or short circuits occur, and the induced current flowing through the pouch-type secondary battery cell is detected at the weld portion of the electrode to determine whether there is a weld defect in the electrode.

Therefore, the present invention can accurately detect whether a crack, short circuit, or weld defect has occurred in a pouch-type secondary battery cell by using the induced current detected from the pouch-type secondary battery cell.

In addition, the present invention can accurately determine the location where a crack, short circuit, or weld defect has occurred by using the induced current detected from the pouch-type secondary battery cell when a defect such as a crack or short circuit, or a weld defect in an electrode, has occurred in the pouch-type secondary battery cell.

In addition, the present invention is not uniform, but allows an induced current to flow through a pouch-type secondary battery cell manufactured in various forms, and detects the induced current at an electrode plate, a bent portion, and a weld portion to determine cracks, short circuits, and weld defects, so that even if there is a positional error between the pouch-type secondary battery cell and the sensor, it has the effect of being able to precisely inspect whether the pouch-type secondary battery cell is defective or not.

### BRIEF DESCRIPTION OF THE DRAWING

Hereinafter, the present invention will be described in more detail through non-limiting embodiments with reference to the attached drawings, and like reference numerals are given to like elements in some drawings.

FIG. 1 is a schematic diagram showing the configuration of a typical pouch-type secondary battery cell.

FIG. 2 is a drawing for explaining the operation of an induced current flowing through a pouch-type secondary battery cell according to the present invention.

FIGS. 3A to 3D are drawings showing examples of installation locations of magnetic field generating means according to the present invention.

FIGS. 4A and 4B are drawings for explaining the operation of inspecting a pouch-type secondary battery cell according to the present invention.

FIGS. 5A to 5C are drawings for explaining the induced current detected by the induced current detection sensor when there is a defect such as a microscopic crack or short circuit in the bent portion.

FIGS. 6A to 6C are drawings for explaining the induced current detected by the induced current detection sensor when there is a defect such as a microscopic crack or short circuit in the electrode plate.

FIG. 7 is a block diagram showing the configuration of the quality inspection device of the present invention.

FIG. 8 is a detailed circuit diagram of the magnetic field generating means of FIG. 7.

FIG. 9 is a block diagram showing the configuration of each of the plurality of signal processing units of FIG. 7, and

FIG. 10 is a signal flow diagram showing a quality inspection method of the present invention.

### DETAILED DESCRIPTION OF THE INVENTION

The following detailed description is merely illustrative and serves to demonstrate embodiments of the present invention. The principles and concepts of the present invention are provided to offer a clear and useful explanation.

Accordingly, the detailed description is not intended to provide a more intricate structure than necessary for a basic understanding of the invention, but rather to illustrate various implementations that can be realized within the scope of the invention through drawings. This approach enables a person with ordinary knowledge in the field to understand the present invention.

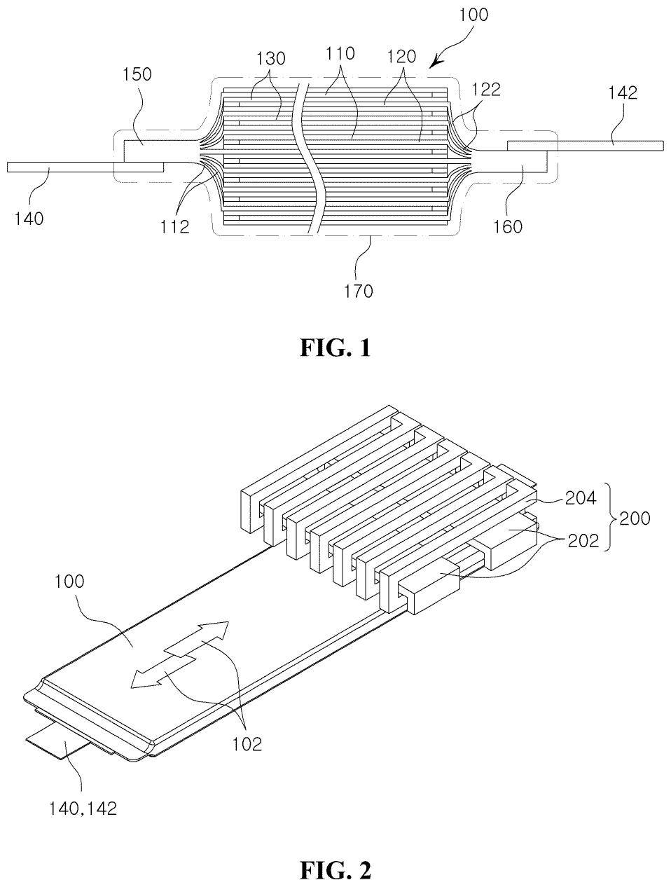

FIG. 1 is a schematic illustration showing the configuration of a typical pouch-type secondary battery cell. Referring to FIG. 1, a pouch-type secondary battery cell (100) may include a plurality of anode electrode plates (110), a plurality of cathode electrode plates (120), and a plurality of separators (130).

A separator (130) is placed between each of the anode electrode plates (110) and cathode electrode plates (120), and they are repeatedly laminated in sequence.

One side portion of the anode electrode plates (110) slightly protrudes beyond one side of the separators (130), while the other side portion of the cathode electrode plates (120) protrudes from the other side of the separators (130).

The length of the protrusion of the anode and cathode electrode plates may vary depending on factors such as the total number of anode plates (110), cathode plates (120), and separators (130), as well as the overall stacking height.

An electrode (150) for welding an anode terminal (140) is integrally formed at one end of the anode electrode plates (110), while an electrode (160) for welding a cathode terminal (142) is integrally formed at one end of the cathode electrode plates (120).

Although this description illustrates and describes an example where the electrodes (150) are formed at one end of the anode plates (110) and the electrodes (160) are formed at the other end of the cathode plates (120), this is not a limitation. The electrodes (150) and (160) can be formed at various locations, including the side surfaces of the anode and cathode plates (110, 120), to prevent short circuits between them.

When welding the anode terminal (140) and cathode terminal (142) to the electrodes (150) and (160), the electrodes are pressed with predetermined pressure from the top and bottom, respectively. The anode and cathode terminals are then welded to the pressed electrodes.

The anode electrode plates (110), cathode electrode plates (120), separators (130), and electrodes (150) and (160) are all sealed inside a pouch (170), along with a predetermined electrolyte.

The pouch (170) is typically made of materials such as an aluminum film.

As a result, the pouch-type secondary battery cell (100) is configured so that only the anode terminal (140) and cathode terminal (142) are exposed outside the pouch (170).

In such pouch-type secondary battery cells (100), during the stacking process of the anode plates (110) and cathode plates (120) with separators (130) interposed between them, defects such as microscopic cracks or short circuits may occur in the anode and cathode electrode plates (110) and (120).

Furthermore, during the pressing process of the electrodes (150) and (160), the ends of the anode electrode plates (110) and cathode electrode plates (120) may bend, creating bent portions (112) and (122). This bending can also lead to defects such as microscopic cracks or short circuits in the bent portions.

The anode electrode plate (110) and cathode electrode plate (120) may be configured so that they do not protrude from the separator (130), with the electrodes (150) and (160) protruding from the separator (130), which results in the formation of the bent portions (112) and (122) on the electrodes.

During the welding process of the anode terminal (140) and the cathode terminal (142) by pressing the electrodes (150) and (160), a weld defect may occur if the electrode (150) is not properly welded to the anode terminal (140), or if the electrode (160) is not properly welded to the cathode terminal (142).

Defects, such as microscopic cracks, short circuits, or weld issues, can cause high temperatures to develop during the charging and discharging processes of pouch-type secondary battery cells, potentially leading to safety hazards like fires.

Therefore, in the present invention, an induced current is generated in a pouch-type secondary battery cell (100). This induced current is detected at the electrode plates (110, 120) and the bent portions (112, 122), allowing for precise detection of defects such as microscopic cracks or short circuits in the electrode plates (110, 120) or bent portions (112, 122).

In addition, in the present invention, an induced current is caused to flow in a pouch-type secondary battery cell (100). The induced current is also detected at the electrodes (150, 160) of the pouch-type secondary battery cell (100), enabling precise detection of any weld defects that may have occurred in the electrodes (150, 160).

FIG. 2 is a diagram illustrating the operation of the induced current flowing to a pouch-type secondary battery cell according to the present invention. In this figure, reference numeral 200 denotes a magnetic field generating means, which consists of, for example, a coil (204) wound a plurality of times around a core (202). The magnetic field generating means (200) applies a magnetic field generating signal of a predetermined frequency to the coil (204), thereby generating a magnetic field.

Then, the magnetic field generating means (200) generates a magnetic field in response to the magnetic field generating signal. This generated magnetic field is induced into the pouch-type secondary battery cell (100), causing an induced current (102) to flow through the cell in accordance with the magnetic field signal.

For example, an induced current (102) flows longitudinally within the pouch-type secondary battery cell (100) due to the magnetic field produced by the magnetic field generating means (200).

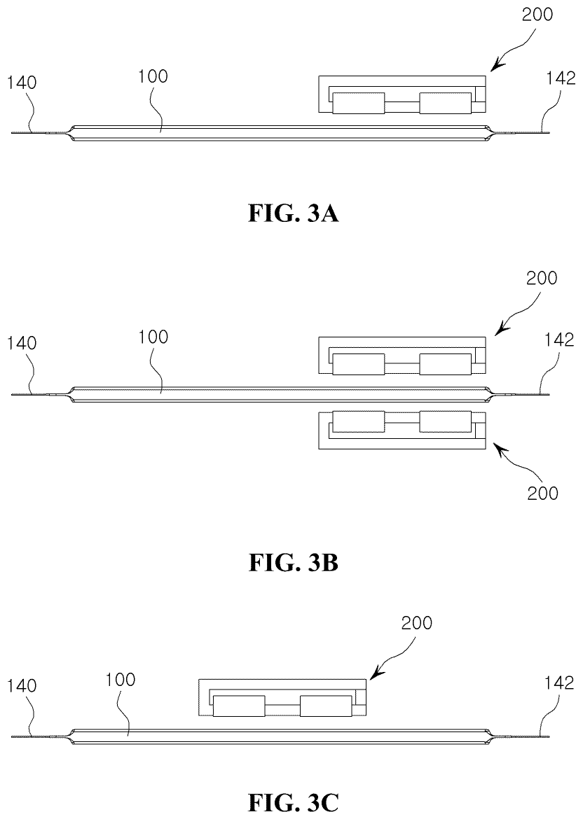

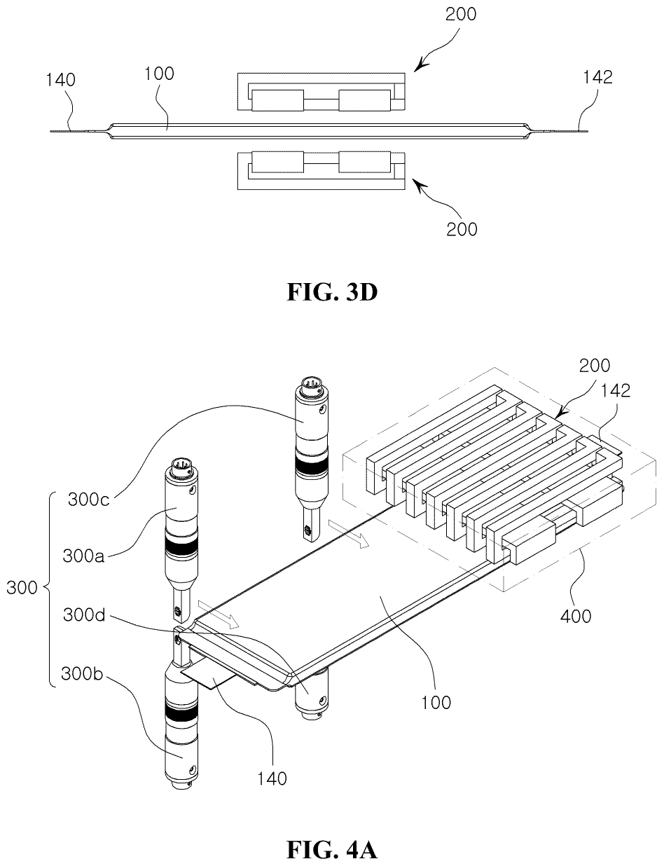

In this invention, the magnetic field generating means (200) can be positioned above one side of the pouch-type secondary battery cell (100), as shown in FIG. 3A, to induce current (102) to flow through the cell.

Additionally, as shown in FIG. 3B, the magnetic field generating means (200) may be positioned both above and below one side of the pouch-type secondary battery cell (100) to induce the current (102) to flow through the cell.

Additionally, as shown in FIG. 3B, the magnetic field generating means (200) may be positioned both above and below one side of the pouch-type secondary battery cell (100) to induce the current (102) to flow through the cell.

Additionally, as shown in FIG. 3C, the magnetic field generating means (200) may be positioned above the middle portion of the pouch-type secondary battery cell (100) to induce an induced current (102) to flow through the cell.

As illustrated in FIG. 3D, the magnetic field generating means (200) may also be positioned above and below the middle portion of the pouch-type secondary battery cell (100) to induce the current (102) to flow through the cell.

In FIGS. 3A to 3D, the placement of the magnetic field generating means (200) that induces current (102) in the pouch-type secondary battery cell (100) is shown and explained as an example.

However, the present invention is not limited to these configurations. The magnetic field generating means (200) can be positioned at various locations, including one side of the pouch-type secondary battery cell (100), where it can induce current (102) to flow through the cell.

Furthermore, the magnetic field generating signal applied to the magnetic field generating means (200) can take various forms, such as different AC signal shapes, including, for example, sine waves or square waves, with frequencies ranging from 60 Hz to 1 MHz.

The induced current (102) flowing into the pouch-type secondary battery cell (100) exhibits frequency characteristics. At higher frequencies, the induced current (102) is larger in the surface layer of the pouch-type secondary battery cell (100), while the current flowing through the intermediate layers is relatively smaller. Conversely, at lower frequencies, the induced current (102) in the intermediate layer gradually increases.

Therefore, in carrying out the present invention, it is preferable to inspect the entire layer of the pouch-type secondary battery cell (100) for defects using a dual-frequency AC signal, which synthesizes both a selected low frequency and a high frequency within the range of 60 Hz to 1 MHz.

Here, the magnetic field generating means (200) is illustrated as an example where a coil (204) with a square cross-section is wound a plurality of times around a core (202). However, the invention is not limited to this configuration, and the magnetic field generating means (200) may be designed in various ways, such as by winding an enamel-coated copper wire as a coil (204) around the core (202).

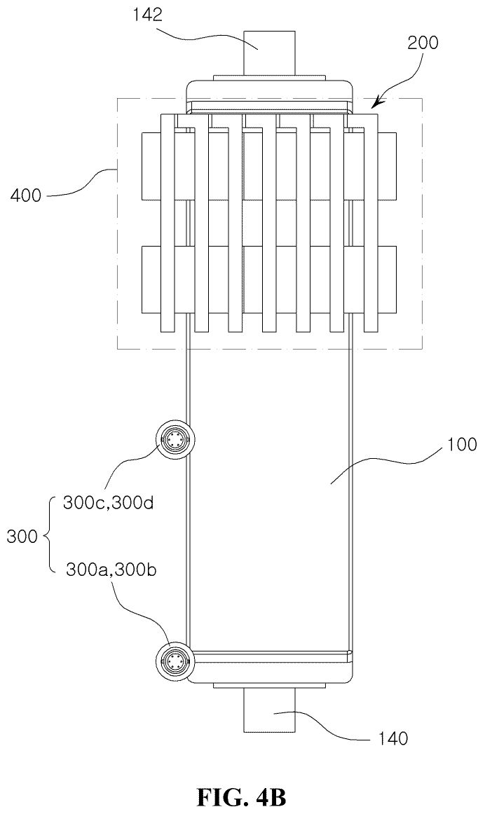

FIG. 4A and FIG. 4B are diagrams explaining the operation for inspecting the quality of a pouch-type secondary battery cell (100) according to the present invention. As shown in FIG. 4A, when the pouch-type secondary battery cell (100) is transported by a conveyor or similar transport means (not shown), it reaches the inspection location where the magnetic field generating means (200) is positioned above the pouch-type secondary battery cell (100).

The position of the magnetic field generating means (200) shown in the drawing is for illustrative purposes only. In practice, the magnetic field generating means (200) may be positioned in various locations to induce current into the pouch-type secondary battery cell (100) as described above.

Additionally, four inductive current detection sensors (300; 300a to 300d) can be positioned adjacent to the pouch-type secondary battery cell (100) to scan the cell and detect the induced current.

For instance, an induced current detection sensor (300a) may scan the upper part of the bent portion (112)(122) of the pouch-type secondary battery cell (100) to detect the induced current, while another sensor (300b) may scan the lower part of the same portion. Similarly, a sensor (300c) may scan the upper part of the electrode plate (110) to detect the induced current, and sensor (300d) may scan the lower part of the electrode plate (110) to detect the induced current.

Although four inductive current detection sensors (300; 300a to 300d) are shown as examples, the number and positioning of these sensors may be adjusted as needed during the implementation of the present invention.

When an AC signal is applied to the coil (204) of the magnetic field generating means (200), it generates a magnetic field. This magnetic field is induced into the pouch-type secondary battery cell (100), causing an induced current to flow through the cell.

The a plurality of inductive current detection sensors (300; 300a to 300d) then scan the pouch-type secondary battery cell (100) across its width to detect the induced current.

If a defect, such as a microscopic crack or short circuit, occurs in the electrode plates (110)(120) or the bent portions (112)(122), it will affect the induced current detected by each of the a plurality of inductive current detection sensors (300; 300a to 300d).

Therefore, in the present invention, the presence or absence of a defect is determined by comparing the detected induced current with a preset judgment criterion range.

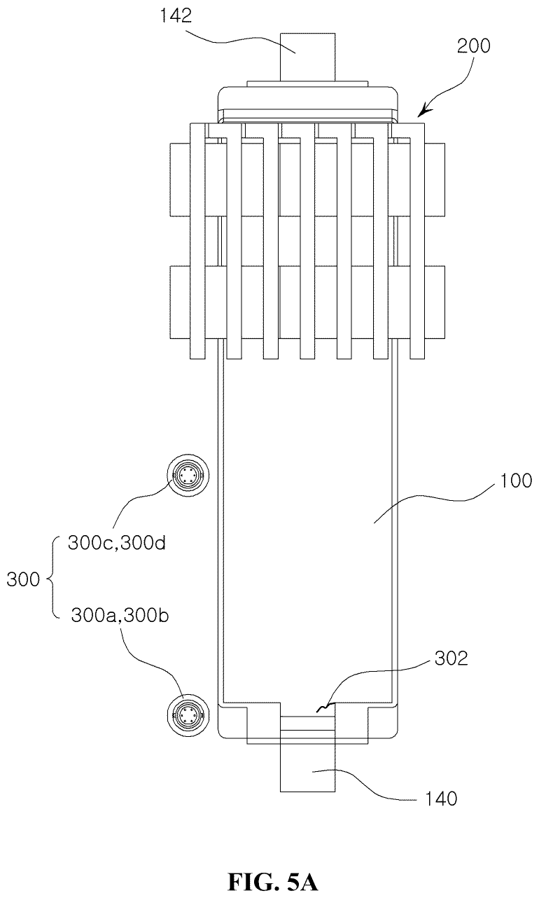

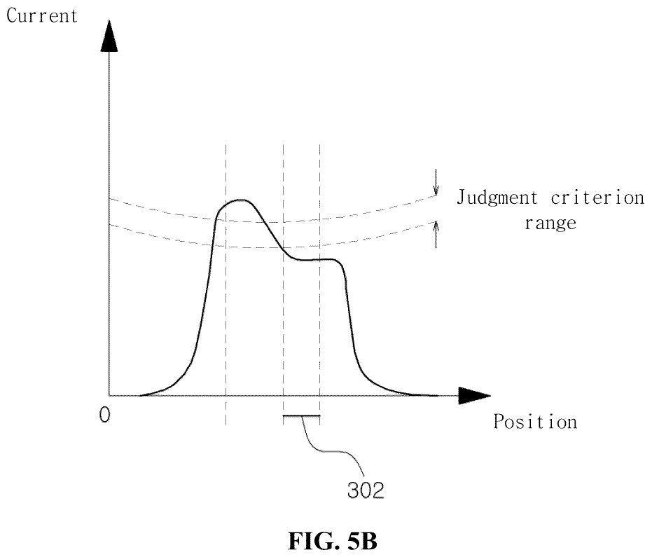

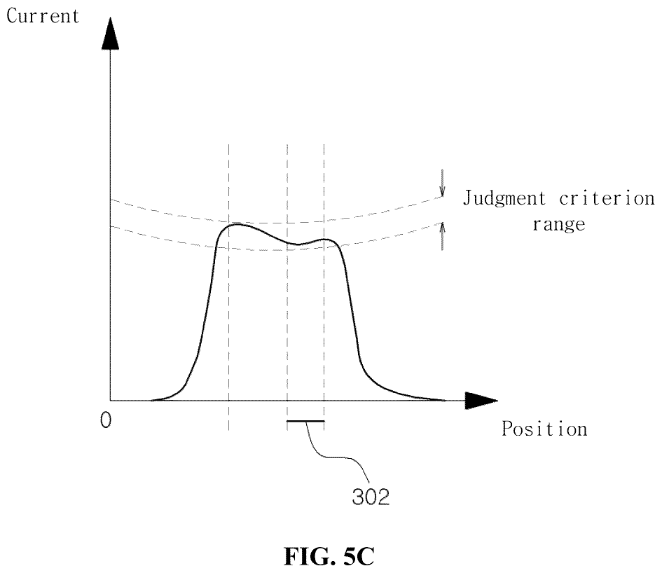

For example, if a microscopic crack (302) occurs in the electrode (140) of the upper layer, as illustrated in FIG. 5A.

Then, the induced current detection sensors (300a) and (300b) scanning the area with the crack (302) will detect a change in the induced current, as shown in FIG. 5B and FIG. 5C.

That is, FIG. 5B shows a graph representing the induced current detected by the upper inductive current detection sensor (300a), while FIG. 5C shows a graph for the lower inductive current detection sensor (300b). When the inductive current detection sensors (300a, 300b) scan a portion of the electrode (140) where no cracks have occurred, a high induced current is detected. However, when the sensors scan an area where a crack is present, a low induced current is observed.

This phenomenon occurs because the induced current flowing to the area with a crack (302) decreases, while the induced current flowing to the area without a crack (302) increases by the amount the induced current has decreased.

Additionally, while the induced current detected by the upper inductive current detection sensor (300a) exhibits significant fluctuations, which fall outside the judgment criterion range, the induced current detected by the lower inductive current detection sensor (300b) displays a lower fluctuation range, indicating that the crack (302) has occurred in the layer of the electrode (112) adjacent to the upper surface layer of the pouch-type secondary battery cell (100).

Therefore, when a defect, such as a crack (302), occurs in the electrode (140)(142), the location and approximate depth of the crack can be determined using the induced current detected by the inductive current detection sensors (300a, 300b).

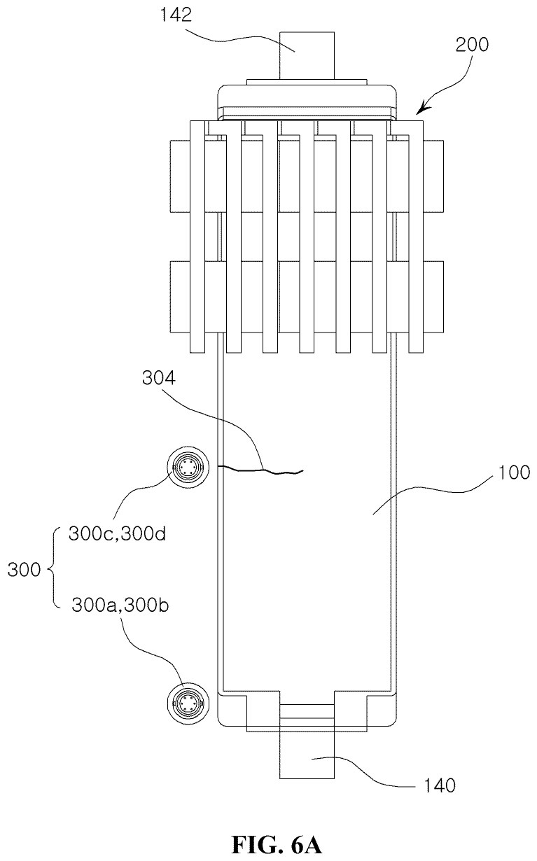

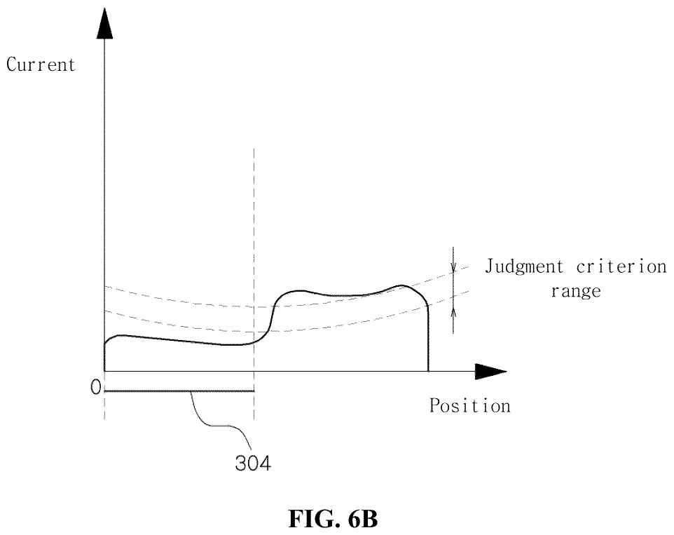

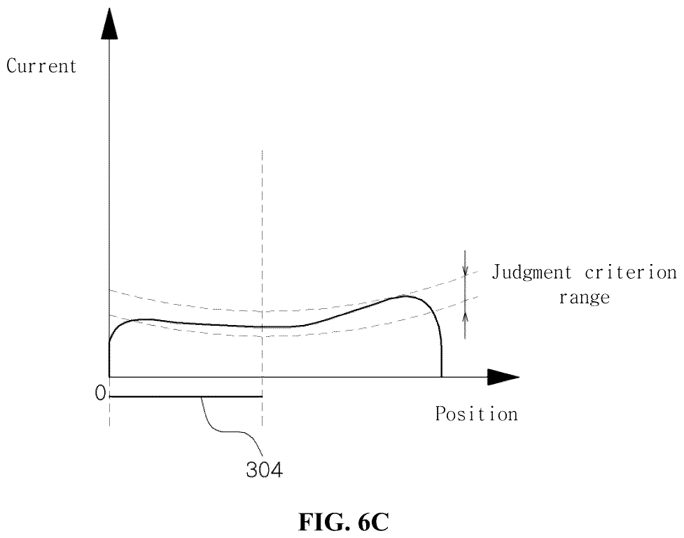

For example, consider the case where a microscopic crack (304) has occurred in the upper layer plate (110, 120), as shown in FIG. 6A.

When the inductive current detection sensors (300c, 300d) scan the electrode plate (110, 120) in the area where the crack (304) has occurred, the induced current is detected, as shown in FIGS. 6B and 6C.

Specifically, FIG. 6B shows the induced current detected by the upper inductive current detection sensor (300c), and FIG. 6C shows the induced current detected by the lower inductive current detection sensor (300d). When these sensors scan the cracked area of the electrode plate (110, 120), a low induced current is detected. Conversely, when they scan areas where no crack has occurred, a relatively high induced current is detected.

This phenomenon is also due to the fact that the induced current flowing to the area where the crack (304) occurred is reduced, and the induced current flowing to the area where the crack (304) did not occur is increased by the amount of the reduced induced current.

Furthermore, the induced current detected by the upper inductive current detection sensor (300c) shows substantial fluctuations, which fall outside the judgment criterion range, while the induced current detected by the lower inductive current detection sensor (300d) has less fluctuation. This suggests that the crack (304) is located in the layer of the electrode plate (112)(122) adjacent to the surface layer of the pouch-type secondary battery cell (100).

In the present invention, a magnetic field signal is applied to the magnetic field generating means (200), inducing an induced current to flow into the pouch-type secondary battery cell (100). Multiple inductive current detection sensors (300) scan various parts of the pouch-type secondary battery cell (100) to detect the induced current.

The induced currents detected by the above-mentioned plurality of inductive current detection sensors (300) are then compared to a predetermined judgment criterion range. Based on this comparison, it is determined whether a defect, such as a crack, exists in the pouch-type secondary battery cell (100).

The example described here involves placing a plurality of inductive current detection sensors (300) in fixed positions on the pouch-type secondary battery cell (100), with the sensors scanning the cell in the width direction.

However, the invention is not limited to this configuration. The inductive current detection sensors (300) can be arranged in both the length and width directions of the pouch-type secondary battery cell (100) to detect induced currents across the entire surface of the pouch-type secondary battery cell (100). In this case, the inductive current detection sensors (300) do not necessarily need to perform a scanning operation.

Additionally, the magnetic field generating means (200) can be fixed, and the pouch-type secondary battery cell (100) can be moved. Once the cell reaches a position where an induced current of sufficient strength flows due to the magnetic field, the inductive current detection sensors (300) move to scan the pouch-type secondary battery cell (100) and detect the induced current. This process is illustrated and explained as an example, but the invention is not limited to this approach.

Alternatively, both the magnetic field generating means (200) and the inductive current detection sensors (300) can be fixed while the pouch-type secondary battery cell (100) is transported. The sensors then scan the pouch-type secondary battery cell (100) to detect the induced current.

The induced currents detected by the sensors may be influenced by the magnetic field generated by the magnetic field generating means (200).

Therefore, a shielding means (400) can be added to prevent the magnetic field by the induced current detection sensors (300) from affecting the induced current detected by the sensors.

The shielding means (400) can shield the magnetic field of the magnetic field generating means (200). For example, the entire area of the magnetic field generating means (200) is surrounded by a magnetic material, as shown in FIGS. 4A and 4B.

Alternatively, although not shown in the drawing, each of the inductive current detection sensors (300) may be equipped with its own shielding means to prevent interference from the magnetic field of the magnetic field generating means (200).

Various shielding techniques can be employed to prevent the magnetic field of the magnetic field generating means (200) from affecting the induced current detection sensors (300).

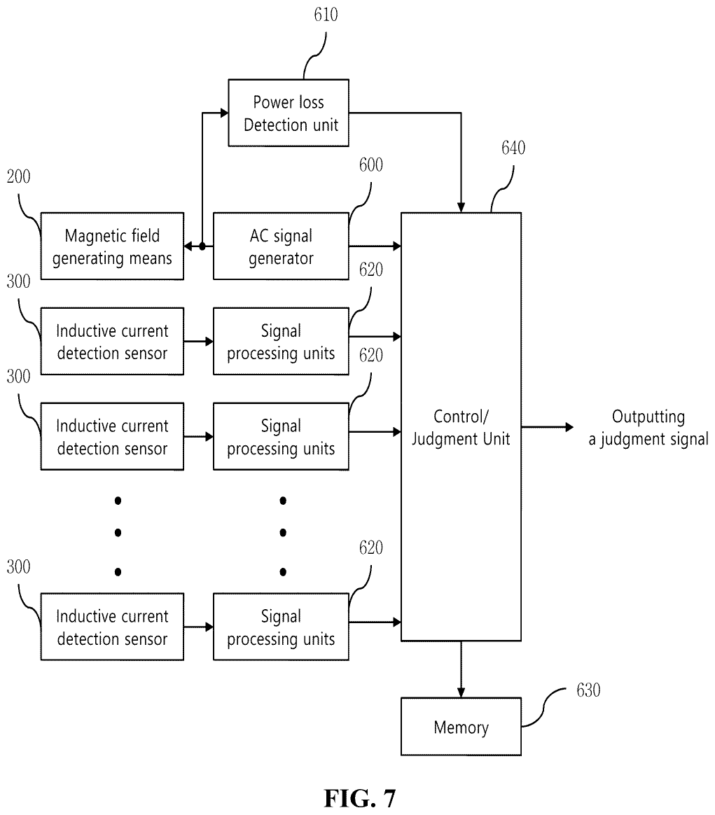

FIG. 7 is a block diagram showing the configuration of the quality inspection device of the present invention. The quality inspection device may include the following components: magnetic field generating means (200), a plurality of inductive current detection sensors (300), an AC signal generating unit (600), a power loss detection unit (610), a plurality of signal processing units (620), a memory (630), and a control/judgment unit (640).

In this configuration, the control/judgment unit (640) controls the AC signal generating unit (600) to produce an AC signal.

The AC signal generating unit (600) can generate various AC signal shapes, including sine and square waves.

The frequency of the AC signal is ideally a dual-frequency signal that synthesizes both low and high frequencies in the range of 60 Hz to 1 MHz.

As explained earlier, the induced current (102) flowing into the pouch-type secondary battery cell (100) exhibits frequency-dependent characteristics: higher frequencies result in more induced current (102) flowing into the surface layer of the pouch-type secondary battery cell (100), while the induced current (102) flowing into the intermediate layer is relatively smaller. At lower frequencies, the induced current in the intermediate layer gradually increases.

Thus, the AC signal generating unit (600) in the present invention generates a dual-frequency AC signal that combines both low and high frequencies within the 60 Hz to 1 MHz range.

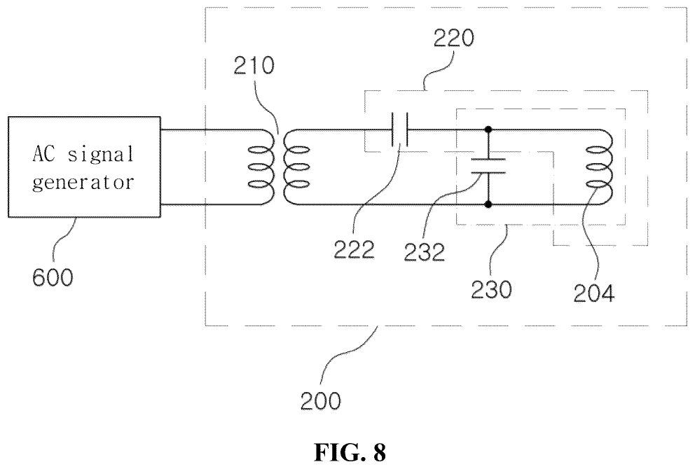

The dual-frequency AC signal generated by the AC signal generating unit (600) is output to the magnetic field generating means (200). The magnetic field generating means (200) may include a transformer (210) for transmitting the dual-frequency AC signal generated by the AC signal generating unit (600) to a coil (204), as shown in FIG. 8. Additionally, it may include a low-frequency resonance unit (220), where a capacitor (222) is connected in series between the transformer (210) and the coil (204) to resonate at a low frequency, and a high-frequency resonance unit (230), where a capacitor (232) is connected in parallel between the transformer (210) and the coil (204) to resonate at a high frequency.

The dual-frequency AC signal generated by the AC signal generating unit (600) passes through the transformer (210) of the magnetic field generating means (200).

In this setup, the coil (204) and capacitor (222) in the low-frequency resonance unit (220) form a series resonance due to the low-frequency AC signal. Similarly, the coil (204) and capacitor (232) in the high-frequency resonance unit (230) form a parallel resonance due to the high-frequency AC signal.

As a result, the coil (204) generates a dual-frequency magnetic field by the dual-frequency AC signal.

The power loss detection unit (610) detects power loss by inputting the AC signal generated by the AC signal generation unit (600) and outputs a detection signal to the control/judgment unit (640).

If the pouch-type secondary battery cell (100) is not in a position suitable for quality inspection, the magnetic field generated by the magnetic field generating means (200) will not be detected as power loss. Therefore, the power loss detection unit (610) will not detect any power loss, and the control/judgment unit (640) can determine that the pouch-type secondary battery cell (100) is not in a position for quality inspection based on this detection signal.

When the pouch-type secondary battery cell (100) is in the correct position for quality inspection, the dual-frequency magnetic field generated by the magnetic field generating means (200) induces a dual-frequency current to flow in the pouch-type secondary battery cell (100). The power loss detection unit (610) will then detect the power loss caused by the magnetic field being induced into the pouch-type secondary battery cell (100).

Then, the control/judgment unit (640) will determine that the pouch-type secondary battery cell (100) is in the inspectable position for quality inspection based on this detection signal.

At this point, a plurality of inductive current detection sensors (300) detect the dual-frequency induced currents at various locations of the pouch-type secondary battery cell (100) and output the signals of the detected dual-frequency induced currents to the corresponding signal processing units (620).

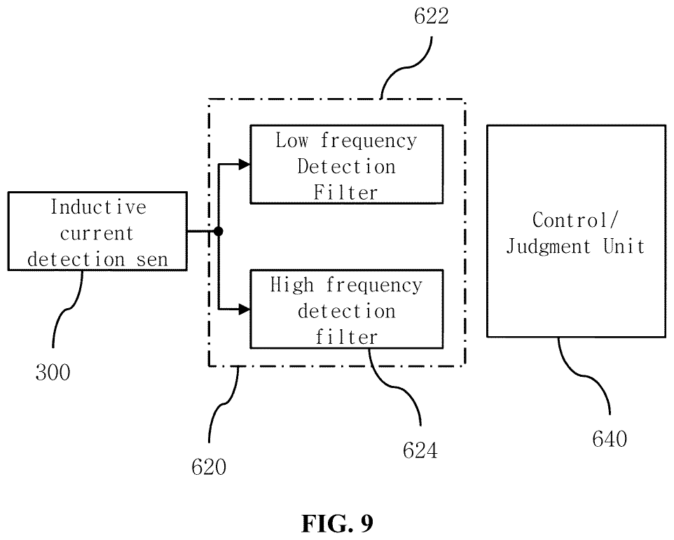

Each signal processing unit (620) may include a low-frequency detection filter (622) and a high-frequency detection filter (624), as shown in FIG. 9.

In the dual-frequency induced current signal detected by each of the inductive current detection sensors (300), the low-frequency induced current signal is detected by the low-frequency detection filter (622) and input into the control/judgment unit (640). Similarly, the high-frequency induced current signal is detected by the high-frequency detection filter (624) and input into the control/judgment unit (640).

The control/judgment unit (640) compares both the low-frequency and high-frequency induced current signals from each signal processing unit (620) with the preset judgment criterion range stored in the memory (630). Based on this comparison, the control/judgment unit (640) determines whether the pouch-type secondary battery cell (100) is defective and generates a judgment signal accordingly.

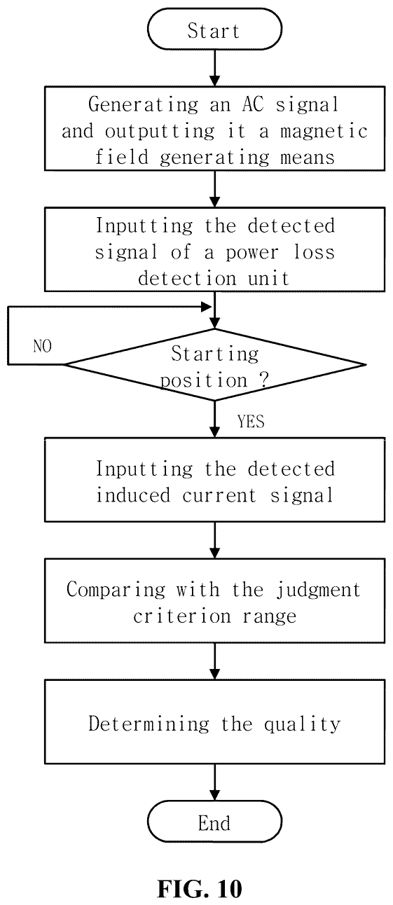

FIG. 10 illustrates a signal flow diagram for the quality inspection method of the present invention. As shown in FIG. 10, under the control of the control/judgment unit (640), the AC signal generation unit (600) generates a dual-frequency AC signal, which is then output to the magnetic field generating means (200) (S1000).

The magnetic field generating means (200) generates a dual-frequency magnetic field according to the dual-frequency AC signal. This magnetic field is induced into the pouch-type secondary battery cell (100), causing a dual-frequency induced current to flow through it.

In this state, the power loss detection unit (610) detects power loss by inputting the dual-frequency AC signal to the AC signal generation unit (600). The control/judgment unit (640) receives the detection signal of this power loss (S1010).

Based on this detection signal, the control/judgment unit (640) determines whether an induced current of sufficient strength is flowing into the pouch-type secondary battery cell (100), i.e., whether the pouch-type secondary battery cell (100) is at a starting position where quality inspection can occur (S1020).

Once the control/judgment unit (640) determines that the pouch-type secondary battery cell (100) is located at a starting position where quality can be inspected, it inputs a dual-frequency induced current signal from the a plurality of signal processing units (620) (S1030).

The control/judgment unit (640) then compares the dual-frequency induced current signal with the values of the judgment criterion range (S1040) and, based on this comparison, determines whether the pouch-type secondary battery cell (100) is good or defective (S1050).

Although the present invention has been described in detail through representative embodiments, those skilled in the art will appreciate that various modifications may be made without departing from the scope of the invention. Some or all of the embodiments may also be selectively combined or configured.

Therefore, the scope of the present invention should not be limited to the described embodiments but should be defined by the claims and their equivalents.

### EXPLANATION OF SYMBOLS

100: Pouch-type secondary battery cell
110: Anode electrode plate
112, 122: Bent portion 120: Cathode electrode plate
130: Separator 140: Terminal
150, 160: Electrode
200: Magnetic field generating means
202: Core 204: Coil
210: Transformer 220: Serial Resonance unit
230: Parallel resonance unit
300; 300a˜300d: Inductive current detection sensor
302, 304: Crack 400: Shielding means
600: AC signal generator
610: Power loss detection unit
620: Signal processing units
622: Low frequency detection filter
624: High frequency detection filter
630: Memory
640: Control/Judgment unit

1. A quality inspection device for a pouch-type secondary battery cell, comprising:
an AC signal generating unit that generates an AC signal;
a magnetic field generating means that generates a magnetic field according to the AC signal and induces a current to flow in the pouch-type secondary battery cell;
at least one inductive current detection sensor for detecting a signal of the inductive current flowing into the pouch-type secondary battery cell; and
a control/judgment unit for comparing the induced current signal detected by the inductive current detection sensor with a value within a preset judgment range and determining the quality of the pouch-type secondary battery cell based on the comparison result.

2. The quality inspection device for a pouch-type secondary battery cell according to claim 1, further comprising a power loss detection unit for detecting power loss in the AC signal generated by the AC signal generating unit;
wherein the control/judgment unit can determine, based on a detection signal of the power loss detection unit, whether the at least one induced current detection sensor is positioned at a start position where it starts detecting an induced current from the pouch-type secondary battery cell.

3. The quality inspection device for a pouch-type secondary battery cell according to claim 1, wherein the magnetic field generating means comprises:
a transformer that transmits the AC current generated by the AC signal generating unit;
a series resonant unit that resonates in series with the low frequency of the AC current to cause a coil to generate a magnetic field; and
a parallel resonance unit that resonates in parallel with the high frequency of the AC current to cause the coil to generate a magnetic field.

4. The quality inspection device for a pouch-type secondary battery cell according to claim 1, further comprising at least one signal processing unit for outputting a signal of the induced current detected by the inductive current detection sensor to the control/judgment unit;
wherein the AC signal generating unit generates an AC signal with dual frequencies, comprising both a low frequency and a high frequency;
wherein the signal processing unit comprises:
a low-frequency detection filter for detecting the low-frequency AC current signal and outputting it to the control/judgment unit; and
a high-frequency detection filter for detecting the high-frequency AC current signal and outputting it to the control/judgment unit.

5. The quality inspection device for a pouch-type secondary battery cell according to claim 1, wherein, the at least one inductive current detection sensor moves and scans the pouch-type secondary battery cell to detect an induced current signal, when the pouch-type secondary battery cell is positioned at a starting position.

6. The quality inspection device for a pouch-type secondary battery cell according to claim 1, wherein the pouch-type secondary battery cell and the at least one inductive current detection sensor are fixed, and the pouch-type secondary battery cell moves such that the induced current signal is detected by being scanned by the at least one inductive current detection sensor.

7. The quality inspection device for a pouch-type secondary battery cell according to claim 1, further comprising a shielding means for shielding the magnetic field generated by the magnetic field generating means, located between the magnetic field generating means and the inductive current detection sensor.

8. A method for inspecting the quality of a pouch-type secondary battery cell, comprising:
a step in which an AC signal generating unit generates an AC signal, and a magnetic field generating means generates a magnetic field according to the generated AC signal and induces a current to flow in the pouch-type secondary battery cell;
a step in which an inductive current detection sensor detects a signal of an induced current flowing into the pouch-type secondary battery cell; and
a step of in which a control/judgment unit compares the signal of the induced current detected by the inductive current detection sensor with a value within a judgment criterion range to determine the quality of the pouch-type secondary battery cell.
